(19) United States
(12) Patent Application Publication
(10) Pub. No.: US 2022/0341677 A1
(43) Pub. Date: Oct. 27, 2022

(54) COOLING MODULE AND METHOD OF MANUFACTURING THE SAME

(71) Applicants: Welfound Tech Co. Ltd., New Taipei City (TW); Shenwei Technology Co., Ltd., New Taipei City (TW)

(72) Inventors: Chun Lin TU, New Taipei City (TW); I Chuan LAI, New Taipei City (TW); Wei Po CHEN, New Taipei City (TW); Chung Lin CHEN, New Taipei City (TW)

(21) Appl. No.: 17/654,980

(22) Filed: Mar. 15, 2022

(30) Foreign Application Priority Data
Apr. 26, 2021 (TW) 110204629

(51) Int. Cl. F28D 15/02; F28D 15/04; F28F 3/02; H05K 7/20

(52) U.S. Cl. CPC F28D 15/0275; F28D 15/04; F28D 15/0233; F28F 3/02; H05K 7/20336; F28F 2275/122

(57) ABSTRACT

A cooling module includes a thermally conductive plate and a heat pipe. The thermally conductive plate includes a groove having two inner walls that are opposite to each other, a first upper protrusion protrusively located on the plate body and the first inner wall, a second upper protrusion protrusively located on the plate body and the second inner wall, a first lower protrusion protrusively located on the first inner wall, and a second lower protrusion protrusively located on the second inner wall. The heat pipe is located in the groove, and cooperatively secured by the first upper protrusion, the second upper protrusion, the first lower protrusion and the second lower protrusion.

### RELATED APPLICATIONS

This application claims priority to Taiwan Application Serial Number 110204629, filed on Apr. 26, 2021, which is herein incorporated by reference.

### BACKGROUND

### Field of Disclosure

The present disclosure relates to a cooling module. More particularly, the present disclosure relates to a cooling module for holding a heat pipe and a manufacturing the cooling module.

### Description of Related Art

A conventional cooling module performs heat exchange with the external environment through circulatory cooling water, so as to meet a purpose of discharging waste heat and cooling circulation.

However, if the quality of the cooling water in the cooling module is less than a specified level, bacteria or fouling may be occurred in the cooling module. Also, if scaling and corrosion are occurred in a pipeline of a system, it may not only cause pipeline blockage and increase flow resistance in a long time, but also damage the life of the cooling module, and further reduce its cooling performance and increase maintenance costs.

It is noted that the above-mentioned technology obviously still has inconvenience and defects, and needs to be further improved. Therefore, how to develop a solution to improve the foregoing deficiencies and inconvenience is an important issue that relevant persons engaged in the industry are currently unable to delay.

### SUMMARY

One aspect of the present disclosure is to provide a cooling module and a method of manufacturing the same to solve the aforementioned problems of the prior art.

In one embodiment of the present disclosure, a cooling module is provided, and the cooling module includes a thermally conductive plate and a heat pipe. The thermally conductive plate includes a plate body, at least one first upper protrusion, at least one second upper protrusion, at least one first lower protrusion and at least one second lower protrusion. The plate body includes a first surface, a second surface and a groove. The first surface and the second surface are opposite to each other. The groove penetrates the plate body to adjoin the first surface and the second surface, respectively. A first inner wall and a second inner wall opposite to each other are defined in groove of the plate body, and the first inner wall and the second inner wall collectively extend along an extending direction. The heat pipe is located in the groove, and cooperatively secured by the first upper protrusion, the second upper protrusion, the first lower protrusion and the second lower protrusion.

According to one or more embodiments of the present disclosure, in the cooling module, the first upper protrusion includes a first convex portion and a first projection tooth. The first convex portion protrudes outwards from the first surface of the plate body. The first projection tooth is connected to one side of the first convex portion and the first inner wall of the plate body, and the first projection tooth extends towards the second upper protrusion. The first projection tooth is formed with a first inclined surface directly pressing an upper surface of the heat pipe.

According to one or more embodiments of the present disclosure, in the cooling module, the second upper protrusion includes a second convex portion and a second projection tooth. The second convex portion protrudes outwards from the first surface of the plate body. The second projection tooth is connected to one side of the second convex portion and the second inner wall of the plate body, and the second projection tooth extends towards the first upper protrusion. The second projection tooth is formed with a second inclined surface directly pressing the upper surface of the heat pipe. A second inclined direction of the second inclined surface is intersected with a first inclined direction of the first inclined surface.

According to one or more embodiments of the present disclosure, in the cooling module, the plate body includes at least one first concave recess and at least one second concave recess. The first concave recess is concavely formed on the second surface of the plate body and connected to the first inclined surface of the first projection tooth. The second concave recess is concavely formed on the second surface of the plate body and connected to the second inclined surface of the second projection tooth.

According to one or more embodiments of the present disclosure, in the cooling module, the first lower protrusion is formed with a third inclined surface directly pressing a lower surface of the heat pipe. The second lower protrusion is formed with a fourth inclined surface directly pressing the lower surface of the heat pipe. A first inclined direction of the first inclined surface is intersected with a third inclined direction of the third inclined surface, the third inclined direction of the third inclined surface is intersected with a fourth inclined direction of the fourth inclined surface.

According to one or more embodiments of the present disclosure, in the cooling module, the first convex portion includes a first top surface and at least one first side surface, the first top surface adjoins the first side surface and the first projection tooth, and the first side surface adjoins the first surface of the plate body. The second convex portion includes a second top surface and at least one second side surface. The second top surface adjoins the second side surface and the second projection tooth, and the second side surface adjoins the second surface of the plate body.

According to one or more embodiments of the present disclosure, in the cooling module, the first top surface of the first convex portion and a first top portion of the first projection tooth are coplanar with each other. The second top surface of the second convex portion and a second top portion of the second projection tooth are coplanar with each other. A first bottom portion of the first lower protrusion, a second bottom portion of the second lower protrusion and the second surface of the plate body are collectively coplanar.

According to one or more embodiments of the present disclosure, in the cooling module, the first upper protrusion, the second upper protrusion, the first lower protrusion and the second lower protrusion are plural in number, respectively. The first upper protrusions and the first lower protrusions are alternately arranged on the first inner wall along the extending direction. The second upper protrusions and the second lower protrusions are alternately arranged on the second inner wall along the extending direction. The heat pipe is directly clamped by the first upper protrusions, the second upper protrusions, the first lower protrusions and the second lower protrusions together.

According to one or more embodiments of the present disclosure, in the cooling module, a thermal conductivity of the heat pipe is greater than a thermal conductivity of the thermally conductive plate.

According to one or more embodiments of the present disclosure, in the cooling module, the heat pipe is with a hollow structure, and a cross section of the heat pipe is hollow and flat.

According to one or more embodiments of the present disclosure, in the cooling module, an upper surface of the at least one first upper protrusion, an upper surface of the at least one second upper protrusion and an upper surface of the heat pipe are flush together.

Thus, through the construction of the embodiments above, the disclosure is able to increase the overall height of the thermally conductive plate, which is helpful to embed a heat pipe which is thicker than conventional one, thereby improving the heat-conducting efficiency of the heat pipe and the thermally conductive plate.

In one embodiment of the present disclosure, a method of manufacturing a cooling module is provided, and the method includes several steps as follows. (a) A thermally conductive plate having a groove thereon is provided; (b) a metal pipe is placed into the groove of the thermally conductive plate; and (c) the metal pipe located in the groove of the thermally conductive plate is squeezed, such that the metal pipe is deformed flat to elongate two opposite longitudinal sides of the metal pipe towards two opposite inner walls of the groove respectively, and the metal pipe is secured in the groove by the a thermally conductive plate.

According to one or more embodiments of the present disclosure, the step (a) further includes that a punching process is performed on a sheet metal piece to form the thermally conductive plate having two upper protrusions and two lower protrusions. The upper protrusions are formed on a top surface of the thermally conductive plate, located on the opposite inner walls of the groove, respectively, and extend toward each other, and the lower protrusions are formed on a bottom surface of the thermally conductive plate, located on the opposite inner walls of the groove, respectively, and extend toward each other, and the groove is connected to the top surface and the bottom surface of the thermally conductive plate, respectively.

According to one or more embodiments of the present disclosure, before the step (b), the method further includes that a pre-pressing procedure is performed at the upper portion and the lower portion of the metal pipe, respectively, such that a pre-pressed upper surface and a pre-pressed lower surface are formed on the metal pipe, respectively.

According to one or more embodiments of the present disclosure, before the step (b), the method further includes that the thermally conductive plate without the metal pipe is disposed on a platform to face the groove towards a load surface of the platform. The step (b) further includes that the metal pipe is placed into the groove through a gap formed between the upper protrusions, and the pre-pressed lower surface of the metal pipe is directly contacted with the load surface of the platform, and the pre-pressed upper surface of the metal pipe protrudes outwardly from the groove. The step (c) further includes that the pre-pressed upper surface of the metal pipe is pressed in a single direction from the metal pipe towards the load surface of the platform, such that the metal pipe that is deformed extends the opposite longitudinal sides thereof to abut against the upper protrusions and the lower protrusions, respectively, and fixedly sandwiched by the upper protrusions and the lower protrusions.

According to one or more embodiments of the present disclosure, before the step (b), the method further includes that the thermally conductive plate without the metal pipe is disposed on a clipping jig having an upper pressing mold and a lower pressing mold which are able to be shut together, and the thermally conductive plate is placed on a pressing area of the lower pressing mold facing towards the upper pressing mold. The step (b) further includes that the metal pipe is placed into the groove through a gap formed between the upper protrusions, wherein the pre-pressed upper surface and the pre-pressed lower surface of the metal pipe are protruded outwards from the groove towards the upper pressing mold and the lower pressing mold, respectively. The step (c) further includes that the pre-pressed upper surface and the pre-pressed lower surface of the metal pipe are simultaneously pressed in confront directions through the clipping jig such that the opposite longitudinal sides of the metal pipe respectively elongate to abut against the upper protrusions and the lower protrusions.

According to one or more embodiments of the present disclosure, the step of simultaneously pressing the pre-pressed upper surface and the pre-pressed lower surface of the metal pipe in confront directions through the clipping jig, further includes a step of thermally pressing the pre-pressed upper surface and the pre-pressed lower surface of the metal pipe through the clipping jig at a specific temperature.

According to one or more embodiments of the present disclosure, the step (a) further includes that a sheet metal piece is punched from one surface to the other surface of the sheet metal piece to form an elongated convex portion on the other surface of the sheet metal piece. The groove is concavely formed on the elongated convex portion, and each of the opposite inner walls of the groove is formed with a hollow portion.

According to one or more embodiments of the present disclosure, the step (b) further includes that the metal pipe is placed onto a bottom plate of the groove, and a width of a cross-section of the metal pipe is less than a minimum width of the groove, and one part of the metal pipe is protruded upwardly from the groove.

According to one or more embodiments of the present disclosure, he step (c) further includes that the part of the metal pipe is rolled and pressed by a rolling tool along a longitudinal direction of the groove such that the opposite longitudinal sides of the metal pipe respectively elongate to abut against the opposite inner walls of the groove. The upper surface of the metal pipe that is flat is flush with the surface of the sheet metal piece.

The above description is merely used for illustrating the problems to be resolved, the technical methods for resolving the problems and their efficacies, etc. The specific details of the present disclosure will be explained in the embodiments below and related drawings.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain the principles of the present disclosure.

FIG. 1 is a perspective view of a cooling module according to one embodiment of the present disclosure.

FIG. 2 is disassembling view of the cooling module of FIG. 1.

FIG. 3 is a cross-sectional view of the cooling module of FIG. 1 viewed along a line A-A.

FIG. 4 is a cross-sectional view of the cooling module of FIG. 2 viewed along a line B-B.

FIG. 5 is a partial enlargement view of an area M of the cooling module of FIG. 2.

FIG. 6 is a cross-sectional view of the cooling module of FIG. 2 viewed along a line C-C.

FIG. 7 is a perspective view of the cooling module of FIG. 1 viewed in a reverse position.

FIG. 8 is a flow chart of a method of manufacturing a cooling module according to one embodiment of the present disclosure.

FIG. 9A to FIG. 9E are continuous operation views of FIG. 8.

FIG. 9F is a cross-sectional view of FIG. 9E viewed along a line D-D.

FIG. 10A to FIG. 100 are continuous operation views of a method of manufacturing a cooling module according to one embodiment of the present disclosure.

FIG. 10D is a cross-sectional view of the cooling module of FIG. 100 according to another embodiment of the present disclosure.

### DESCRIPTION OF THE EMBODIMENTS

Reference will now be made in detail to the present embodiments of the present disclosure, examples of which are illustrated in the accompanying drawings. Wherever possible, the same reference numbers are used in the drawings and the description to refer to the same or like parts. According to the embodiments, it will be apparent to those skilled in the art that various modifications and variations can be made to the structure of the present disclosure without departing from the scope or spirit of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

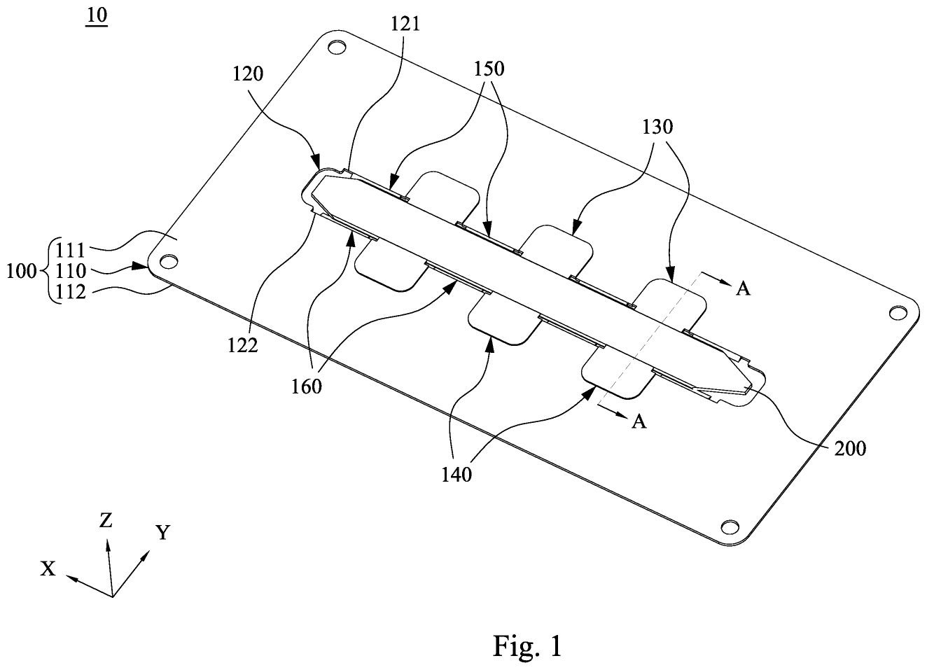

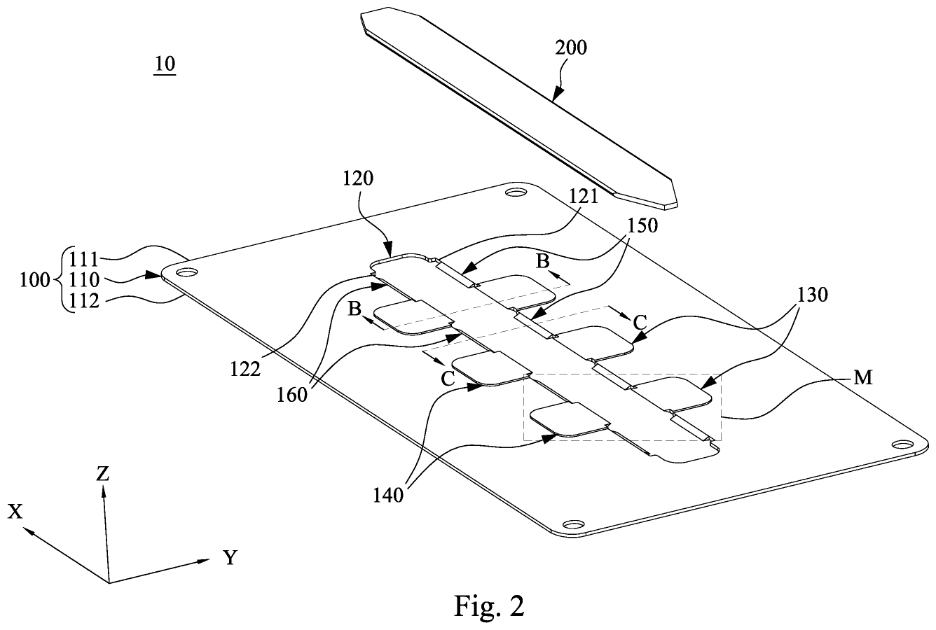

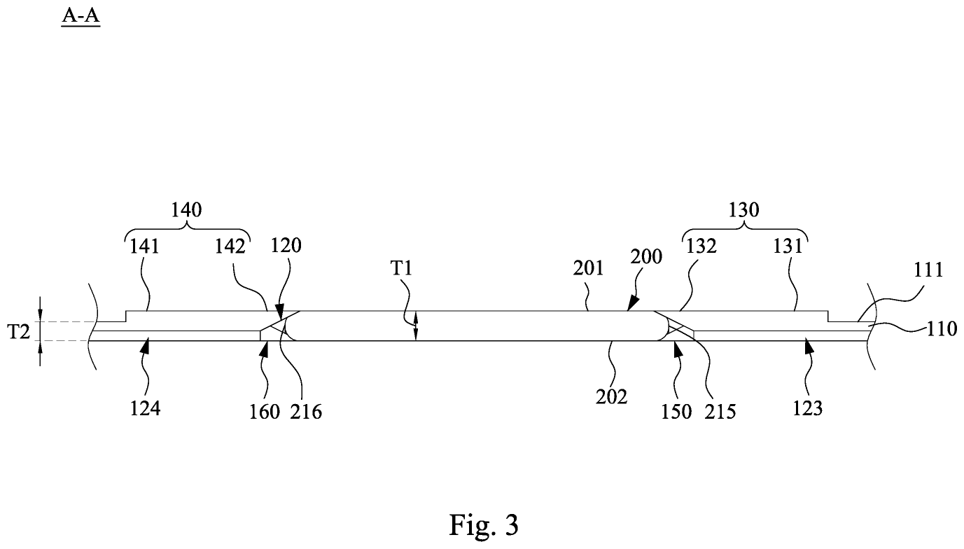

Reference is now made to FIG. 1 to FIG. 2, in which FIG. 1 is a perspective view of a cooling module 10 according to one embodiment of the present disclosure, FIG. 2 is disassembling view of the cooling module 10 of FIG. 1, and FIG. 3 is a cross-sectional view of the cooling module 10 of FIG. 1 viewed along a line A-A. As shown in FIG. 1 to FIG. 3, in the embodiment, the cooling module 10 includes a thermally conductive plate 100 and a heat pipe 200. The thermally conductive plate 100 includes a plate body 110, a plurality of first upper protrusions 130, a plurality of second upper protrusions 140, a plurality of first lower protrusions 150 and a plurality of second lower protrusions 160. The plate body 110 includes a first surface 111 and a second surface 112 which are opposite to each other. The plate body 110 further includes a through groove 120. In the embodiment, the through groove 120 is in a linear shape, however, the disclosure is not limited thereto. The through groove 120 penetrates through the plate body 110 to adjoin the first surface 111 and the second surface 112, respectively, however, in another embodiment, the groove may be a blind hole. A first inner wall 121 and a second inner wall 122 opposite to each other are defined in the through groove 120 of the plate body 110, and the first inner wall 121 and the second inner wall 122 collectively extend along an extending direction (e.g., X axis). The aforementioned extending direction (e.g., X axis) and a long-axis direction (e.g., X axis) of the through groove 120 are parallel to each other.

The first upper protrusions 130 are spaced arranged on the plate body 110 in the extending direction (e.g., X axis). Each of the first upper protrusions 130 is located on the first surface 111 and the first inner wall 121 of the plate body 110, and extends towards the corresponding one of the second upper protrusions 140. The second upper protrusions 140 are spaced arranged on the plate body 110 in the extending direction (e.g., X axis). Each of the second upper protrusions 140 is located on the first surface 111 and the second inner wall 122 of the plate body 110 and extends towards the corresponding one of the first upper protrusions 130. An upper surface of each of the first upper protrusions 130, an upper surface of the corresponding one of the second upper protrusions 140 and an upper surface 201 of the heat pipe 200 are flush together. (FIG. 3).

The first lower protrusions 150 are spaced arranged within the through groove 120 in the extending direction (e.g., X axis). Each of the first lower protrusions 150 is located on the first inner wall 121, and extends towards the second inner wall 122 (or the corresponding one of the second lower protrusions 160). The first lower protrusions 150 and the first upper protrusions 130 are alternately arranged on the first inner wall 121 along the extending direction (e.g., X axis). The second lower protrusions 160 are spaced arranged within the through groove 120 in the extending direction (e.g., X axis). Each of the second lower protrusions 160 is located on the second inner wall 122 of the plate body 110, and extends towards the first inner wall 121 (or the corresponding one of the first lower protrusions 150). The second upper protrusions 140 and the second lower protrusions 160 are alternately arranged on the second inner wall 122 along the extending direction (e.g., X axis). The heat pipe 200 is located in the through groove 120, and cooperatively secured by the first upper protrusion 130, the second upper protrusion 140, the first lower protrusion 150 and the second lower protrusion 160 (FIG. 3). In the embodiment, the heat pipe 200 is in a linear shape for example as a cylinder, and a long-axis direction (e.g., X axis) of the heat pipe 200 and the long-axis direction (e.g., X axis) of the through groove 120 are parallel to each other, however, the disclosure is not limited thereto, in another embodiment, the heat pipe 200 may also be in U-shaped.

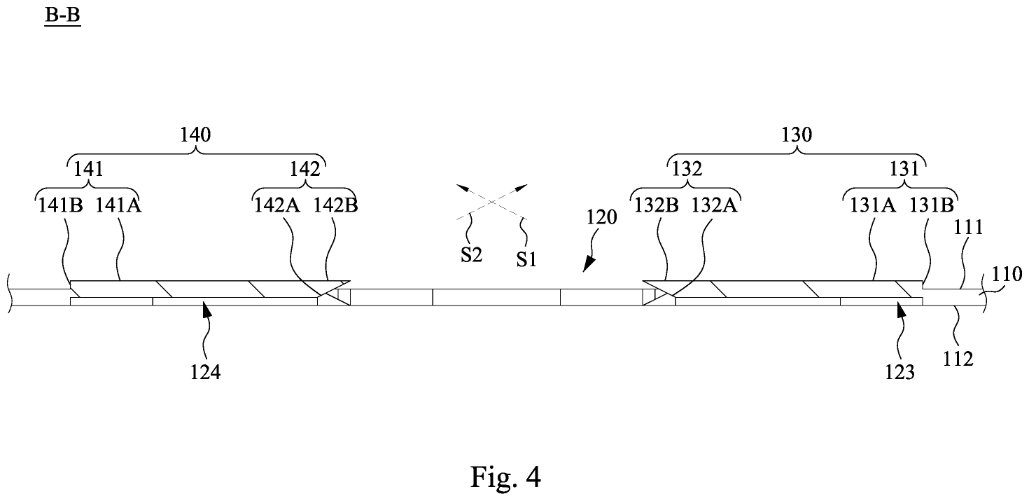

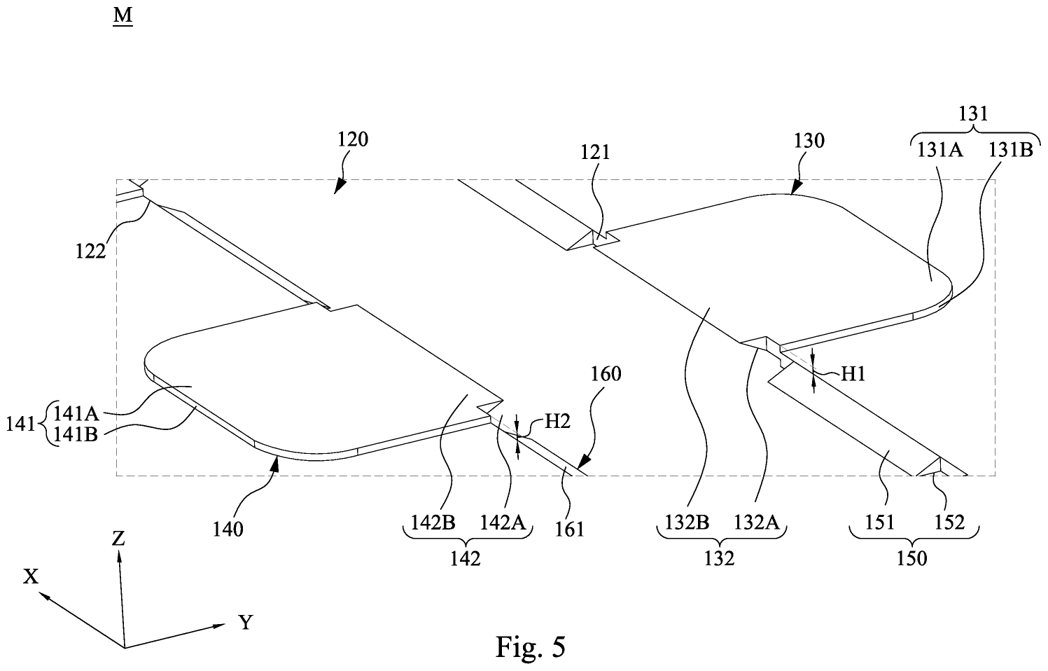

Reference is now made to FIG. 4 and FIG. 5 in which FIG. 4 is a cross-sectional view of the cooling module 10 of FIG. 2 viewed along a line B-B, and FIG. 5 is a partial enlargement view of an area M of the cooling module 10 of FIG. 2. More specifically, as shown in FIG. 4 and FIG. 5, each of the first upper protrusions 130 includes a first convex portion 131 and a first projection tooth 132. The first convex portion 131 protrudes outwards from the first surface 111 of the plate body 110. A vertical height H1 of the first convex portion 131 to the first surface 111 of the plate body 110 along the Z axis is, for example, 0.2 mm, however, the disclosure is not limited thereto. The first projection tooth 132 is connected to one side of the first convex portion 131 and the first inner wall 121 of the plate body 110, and the first projection tooth 132 extends towards the second upper protrusion 140.

In the embodiment, each of the first projection tooth 132 is, for example, in a wedge-shaped shape, and each of the first projection tooth 132 is formed with a first inclined surface 132A and a first top portion 132B. The first top portion 132B is adjoined to the first inclined surface 132A, and not substantially coplanar with the first surface 111 of the plate body 110. The first inclined surface 132A is used to directly press the upper surface 201 of the heat pipe 200 (FIG. 3). The first inclined surface 132A extends along a first inclined direction (e.g., axial direction S1, FIG. 4). The first inclined direction (e.g., axial direction S1, FIG. 4) is to gradually approach the central position of the through groove 120 along a direction from the second surface 112 of the plate body 110 to the first surface 111 thereof, and the first inclined direction (e.g., axial direction S1, FIG. 4) and the aforementioned extending direction (e.g., X axis) are intersected with each other.

More specifically, the first convex portion 131 includes a first top surface 131A and one or more first side surfaces 131B. The first top surface 131A adjoins the first side surfaces 131B and the first projection tooth 132, and the first side surfaces 131B adjoin the first surface 111 of the plate body 110. The first top surface 131A of the first convex portion 131 and the first top portion 132B of the first projection tooth 132 are substantially coplanar.

In the embodiment, as shown in FIG. 5, the first convex portion 131 is integrally formed on the first surface 111 of the plate body 110. The first projection tooth 132 is integrally formed on both of the first convex portion 131 and the first inner wall 121 of the plate body 110, however, the disclosure is not limited thereto.

Each of the second upper protrusions 140 includes a second convex portion 141 and a second projection tooth 142. The second convex portion 141 protrudes outwards from the first surface 111 of the plate body 110. A vertical height H2 of the second convex portion 141 to the first surface 111 of the plate body 110 along the Z axis is, for example, 0.2 mm, however, the disclosure is not limited thereto. The second projection tooth 142 is connected to one side of the second convex portion 141 and the second inner wall 122 of the plate body 110, and the second projection tooth 142 extends towards the first upper protrusion 130. Each of the second projection tooth 142 is, for example, in a wedge-shaped shape, and each of the second projection tooth 142 is formed with a second inclined surface 142A and a second top portion 142B. The second top portion 142B is adjoined to the second inclined surface 142A, and not substantially coplanar with the first surface 111 of the plate body 110. The second inclined surface 142A is used to directly press the upper surface 201 of the heat pipe 200 (FIG. 3). The second inclined surface 142A extends along a second inclined direction (e.g., axial direction S2, FIG. 4). The second inclined direction (e.g., axial direction S2, FIG. 4) is to gradually approach the central position of the through groove 120 along a direction from the second surface 112 of the plate body 110 to the first surface 111 thereof. The second inclined direction (e.g., axial direction S2, FIG. 4) and the aforementioned extending direction (e.g., X axis) are intersected with each other, and the second inclined direction (e.g., axial direction S2, FIG. 4) of the second inclined surface 142A is intersected with the first inclined direction (e.g., axial direction S1, FIG. 4) of the first inclined surface 132A.

More specifically, the second convex portion 141 includes a second top surface 141A and one or more second side surfaces 141B. The second top surface 141A adjoins the second side surface 141B and the second projection tooth 142, and the second side surface 141B adjoins the first surface 111 of the plate body 110. The second top surface 141A of the second convex portion 141 and the second top portion 142B of the second projection tooth 142 are substantially coplanar.

In the embodiment, as shown in FIG. 5, the second convex portion 141 is integrally formed on the first surface 111 of the plate body 110. The second projection tooth 142 is integrally formed on both of the second convex portion 141 and the second inner wall 122 of the plate body 110, however, the disclosure is not limited thereto.

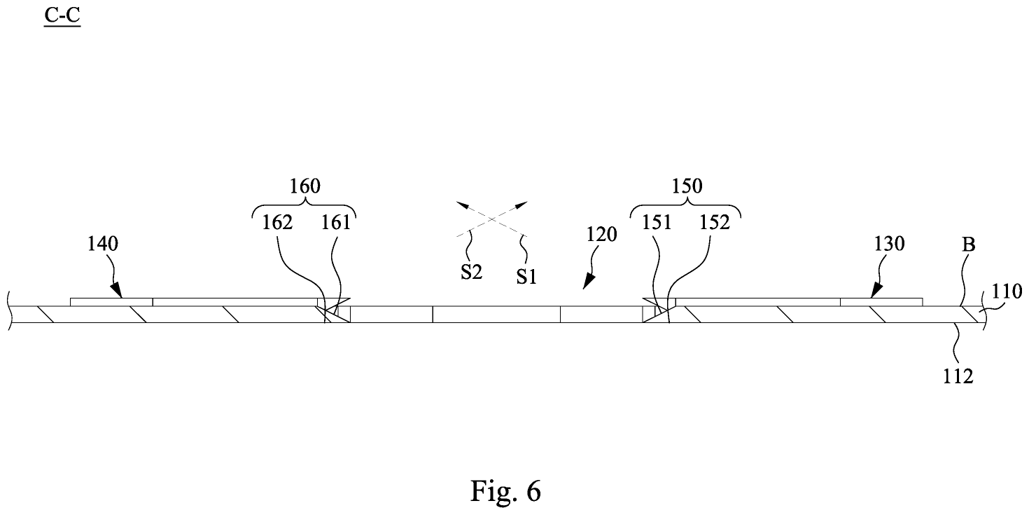

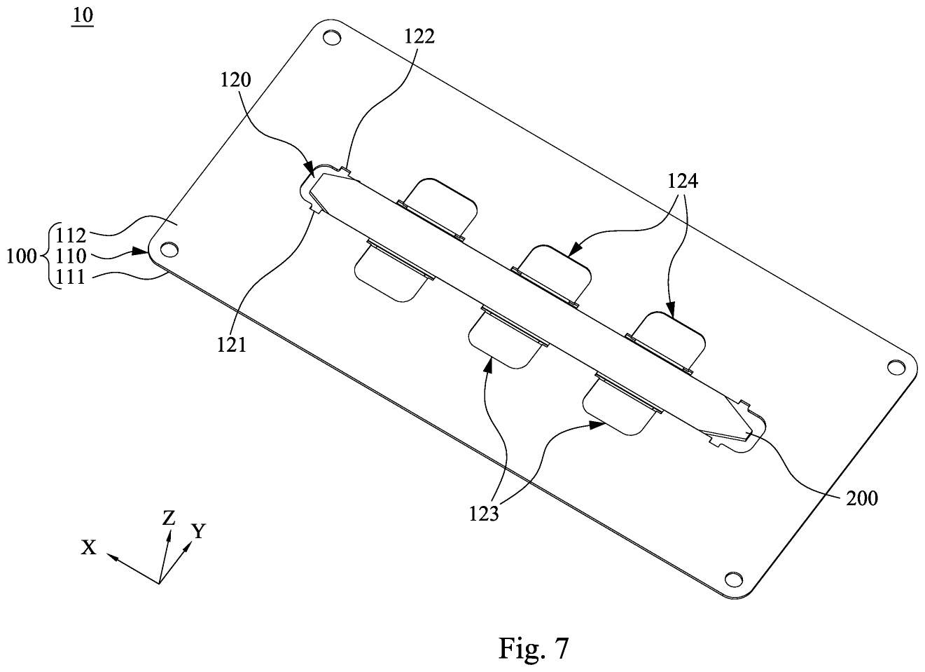

FIG. 6 is a cross-sectional view of the cooling module 10 of FIG. 2 viewed along a line C-C. As shown in FIG. 5 and FIG. 6, in the embodiment, the first lower protrusion 150 is, for example, in a wedge-shaped shape, and the first lower protrusion 150 is formed with a third inclined surface 151 and a first bottom portion 152. The first bottom portion 152 is adjoined to the third inclined surface 151, and substantially coplanar with the second surface 112 of the plate body 110. The third inclined surface 151 is used to directly press a lower surface 202 of the heat pipe 200. The third inclined surface 151 extends along a third inclined direction (e.g., axial direction S2, FIG. 4). The third inclined direction (e.g., axial direction S2, FIG. 4) is to gradually approach the central position of the through groove 120 along a direction from the first surface 111 of the plate body 110 to the second surface 112 thereof, and the third inclined direction (e.g., axial direction S2, FIG. 4) is intersected with the aforementioned extending direction (e.g., X axis). For example, but not limited thereto, the third inclined direction (e.g., axial direction S2) is parallel to the second inclined direction (e.g., axial direction S2).

As shown in FIG. 5 and FIG. 6, in the embodiment, the second lower protrusion 160 is, for example, in a wedge-shaped shape, and the second lower protrusion 160 is formed with a fourth inclined surface 161 and a second bottom portion 162. The second bottom portion 162 is adjoined to the fourth inclined surface 161, and substantially coplanar with the second surface 112 of the plate body 110. The fourth inclined surface 161 is used to directly press the lower surface 202 of the heat pipe 200. The fourth inclined surface 161 extends along a fourth inclined direction (e.g., axial direction S1, FIG. 4). The fourth inclined direction (e.g., axial direction S1, FIG. 4) is to gradually approach the central position of the through groove 120 along the direction from the first surface 111 of the plate body 110 to the second surface 112 thereof. The fourth inclined direction (e.g., axial direction S1, FIG. 4) is intersected with the aforementioned extending direction (e.g., X axis), and is intersected with the second inclined direction (e.g., axial direction S2, FIG. 4). For example, but not limited thereto, the fourth inclined direction (e.g., axial direction S1) is parallel to the first inclined direction (e.g., axial direction S1).

FIG. 7 is a perspective view of the cooling module 10 of FIG. 1 viewed in a reverse position. As shown in FIG. 3 and FIG. 7, the plate body 110 includes a plurality of first concave recesses 123 and a plurality of second concave recesses 124. The first concave recesses 123 are spaced arranged on the plate body 110 in the extending direction (e.g., X axis). Each of the first concave recesses 123 is concavely formed on the second surface 112 of the plate body 110, connected to the first inclined surface 132A of the first projection tooth 132, and overlapped with the corresponding one of the first upper protrusions 130 (FIG. 3). The second concave recesses 124 are spaced arranged on the plate body 110 in the extending direction (e.g., X axis). Each of the second concave recesses 124 is concavely formed on the second surface 112 of the plate body 110, connected to the second inclined surface 142A of the second projection tooth 142, and overlapped with the corresponding one of the second upper protrusions 140 (FIG. 3).

Furthermore, as shown in FIG. 3 and FIG. 7, a thermal conductivity of the heat pipe 200 is greater than a thermal conductivity of the thermally conductive plate 100, and a maximum thickness T1 of the heat pipe 200 is greater than a maximum thickness T2 of the plate body 110. For example, the maximum thickness T1 of the heat pipe 200 is 0.8 mm, and the maximum thickness T2 of the plate body 110 is 0.6 mm, however, the disclosure is not limited thereto. More specifically, the heat pipe 200 is with a hollow structure, and a cross section of the heat pipe is hollow and flat.

Thus, through the construction of the embodiments above, the disclosure is able to increase the overall height of the thermally conductive plate, which is helpful to embed a heat pipe which is thicker than conventional one, thereby improving the heat-conducting efficiency of the heat pipe and the thermally conductive plate.

It is noted, although the first upper protrusions 130, the second upper protrusions 140, the first lower protrusions 150 and the second lower protrusions 160 are plural, and the first upper protrusions 130 and the second upper protrusions 140 are the same in number, and the first lower protrusions 150 and the second lower protrusions 160 are the same in number, however, the disclosure is not limited thereto. In another embodiment, the first upper protrusions 130, the second upper protrusions 140, the first lower protrusions 150 and the second lower protrusions 160 are not the same in number; or each of the first upper protrusion 130, the second upper protrusion 140, the first lower protrusion 150 and the second lower protrusion 160 is only single in number.

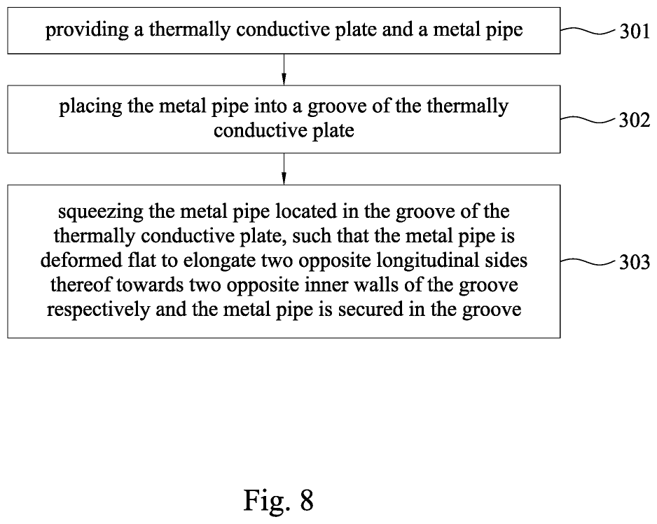

FIG. 8 is a flow chart of a method of manufacturing a cooling module according to one embodiment of the present disclosure. As shown in FIG. 8, in the embodiment, the method of manufacturing a cooling module includes step 301 to step 303 as follows. In the step 301, a thermally conductive plate and a metal pipe are provided; in the step 302, the metal pipe is placed into a groove of the thermally conductive plate; in the step 303, the metal pipe located in the groove of the thermally conductive plate is squeezed such that the metal pipe is deformed flat to elongate two opposite longitudinal sides of the metal pipe towards two opposite inner walls of the groove respectively, thereby securing the metal pipe in the groove.

As shown in FIG. 2 and FIG. 8, in the step 301 of the embodiment, the method further includes that a punching process is performed on a sheet metal piece to form the thermally conductive plate 100 mentioned above (FIG. 2). More specifically, during the punching process, the sheet metal piece is able to be sequentially formed with the first upper protrusions 130, the second upper protrusions 140, the first lower protrusions 150 and the second lower protrusions 160 (FIG. 2). It is noted, since the workpiece stamping is a known technology, so it will not be repeated here.

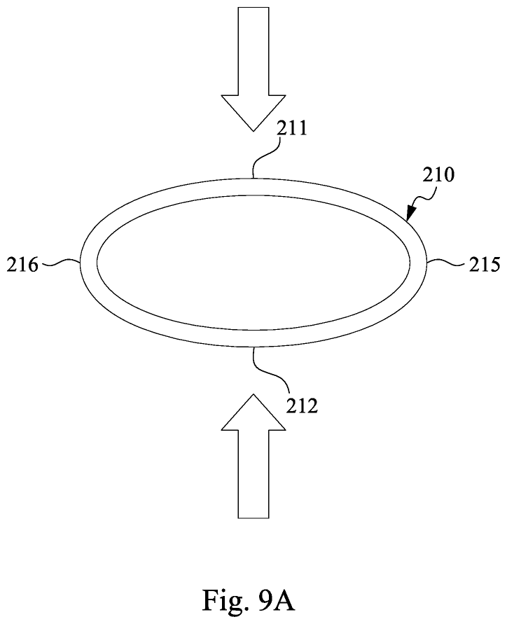

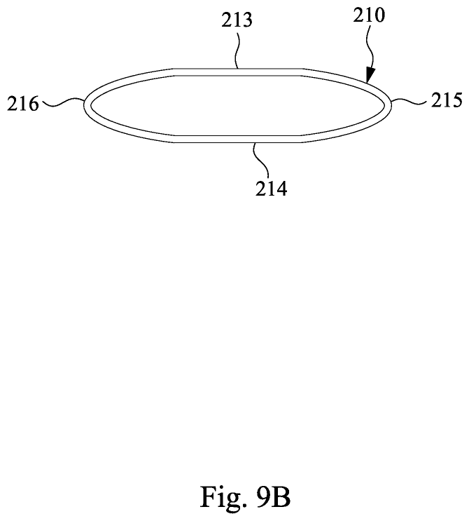

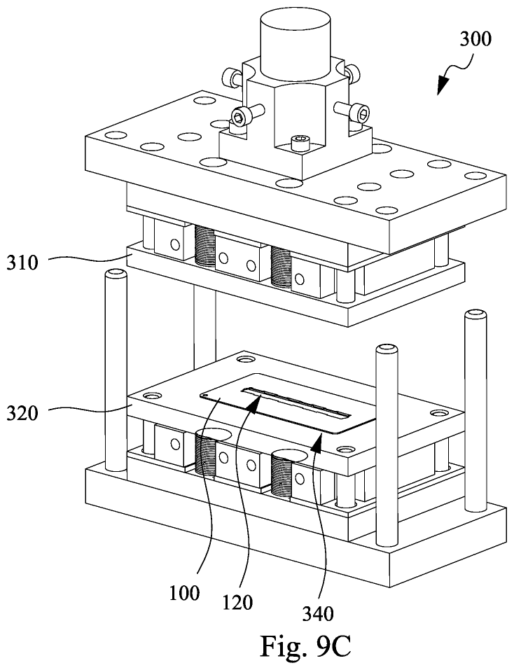

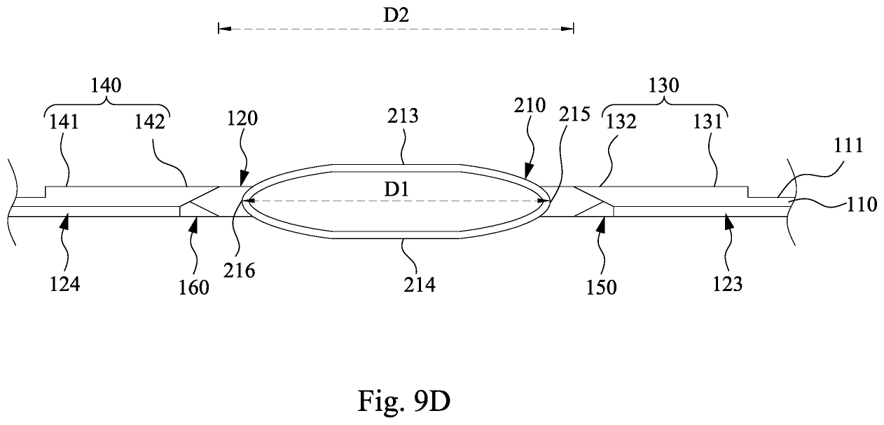

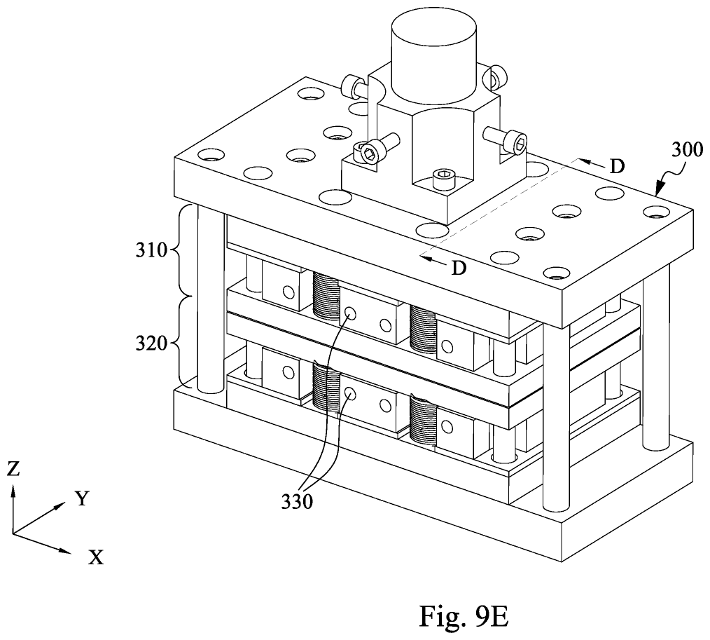

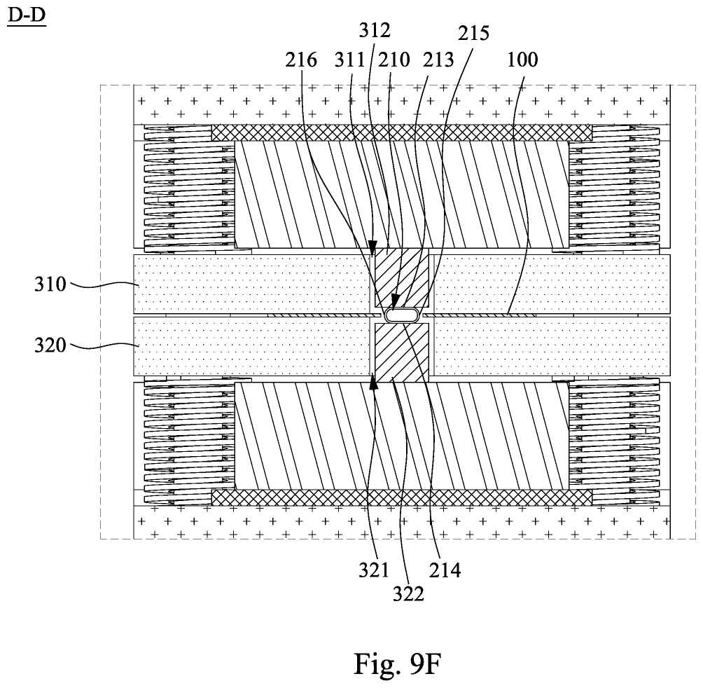

FIG. 9A to FIG. 9E are continuous operation views of FIG. 8. FIG. 9F is a cross-sectional view of FIG. 9E viewed along a line D-D. As shown in FIG. 9A to FIG. 9B, the method further includes a detailed step between step 301 and step 302, described as follow. A pre-pressing procedure is performed on the metal pipe 210 at an upper portion 211 and a lower portion 212 of the metal pipe 210, respectively. More specifically, the upper portion 211 and the lower portion 212 of the metal pipe 210 are pre-pressed synchronously or sequentially to form a pre-pressed upper surface 213 and a pre-pressed lower surface 214 on the metal pipe 210, respectively. The pre-pressed upper surface 213 and the pre-pressed lower surface 214 are substantially opposite to each other, and are configured parallel. However, the disclosure is not limited to this, and in other embodiments, this detailed step may also be omitted, that is, the metal pipe 210 also can be skipped to step 302 and 303 without going through the pre-pressing procedure.

As shown in FIG. 9C and FIG. 9E, in this embodiment, the method further includes some detailed steps as follows. Firstly, a clipping jig 300 is provided, and the clipping jig 300 includes an upper pressing mold 310 and a lower pressing mold 320 which are able to be shut together. For example, the upper pressing mold 310 includes an upper cavity 311 and an upper pressing block 312 located within the upper cavity 311 of the upper pressing mold 310. The lower pressing mold 320 includes a lower cavity 321 and a lower pressing block 322 located within the lower cavity 321, and the upper cavity 311 and the lower cavity 321 are aligned and communicated with each other (FIG. 9F).

Next, as shown in FIG. 9C, the upper pressing mold 310 and the lower pressing mold 320 are opened so that the thermally conductive plate 100 without the metal pipe can be disposed on a pressing area 340 of the lower pressing mold 320 facing towards the upper pressing mold 310.

Next, as shown in FIG. 9D, the metal pipe 210 is placed into the groove 120 through a gap formed between the first upper protrusions 130 and the second upper protrusions 140. At this moment, the cross-sectional width D1 of the metal pipe 210 is not greater than the minimum linear distance D2 between the first upper protrusions 130 and the second upper protrusions 140, and the pre-pressed upper surface 213 and the pre-pressed lower surface 214 of the metal pipe 210 are protruded outwards from the groove 120 towards the upper pressing mold 310 and the lower pressing mold 320, respectively.

Next, as shown in FIG. 9E and FIG. 9F, when the upper pressing mold 310 and the lower pressing mold 320 are shut, the thermally conductive plate 100 is sandwiched between the upper pressing mold 310 and the lower pressing mold 320, and the metal pipe 210 placed within the through groove 120 (FIG. 9D) is exactly disposed within the upper cavity 311 and the lower cavity 321 which are in communication with each other. More particularly, when the clipping jig 300 is operated to shut the upper pressing mold 310 and the lower pressing mold 320 to simultaneously press the pre-pressed upper surface 213 and the pre-pressed lower surface 214 of the metal pipe 210 in confront directions according to a specific pressure value.

Thus, as shown FIG. 3, the opposite longitudinal sides 215, 216 of the metal pipe 210 respectively elongate to abut against the first upper protrusions 130, the second upper protrusions 140, the first lower protrusions 150 and the second lower protrusions 160, respectively. Thus, the metal pipe 210 is fixedly clamped by the first upper protrusions 130, the second upper protrusions 140, the first lower protrusions 150 and the second lower protrusions 160.

Furthermore, each of the upper pressing mold 310 and the lower pressing mold 320 is provided with heating tubes 330 spaced arranged therein. The heating tubes 330 are parallel to each other (e.g., Y axis), and the long axis direction (e.g., X axis) of the metal pipe 210 is perpendicular to the long axis direction (e.g., Y axis) of each of the heating tubes 330.

Therefore, when the upper pressing mold 310 and the lower pressing mold 320 are shut together along Z axis for squeezing the metal pipe 210, the clipping jig 300 also heats the upper pressing block 312 and the lower pressing block 322 through the heating tubes 330 at a specific temperature, thus, the clipping jig 300 can thermally press the pre-pressed upper surface 213 and the pre-pressed lower surface 214 of the metal pipe 210 by the upper pressing block 312 and the lower pressing block 322.

In this way, since the metal pipe 210 is instantly heated by the clipping jig 300 to a certain temperature, a working fluid filled in the metal pipe 210 can be evaporated to generate air pressure inside the metal pipe 210 so as to evenly confront the pressing force of the clipping jig 300. Thus, the corresponding areas of the metal pipe 210 will not easy to be dented by the clipping jig 300. However, the disclosure is not limited thereto.

Comparing to the press of the metal pipe 210 from the confront directions, the method in another embodiment further includes steps as follows. At first, the thermally conductive plate without the metal pipe is disposed on a platform (not shown in figure) to face the groove towards a load surface of the platform. Next, the metal pipe is placed into the groove through a gap formed between the first upper protrusions, the second upper protrusions, and the pre-pressed lower surface of the metal pipe is directly contacted with the load surface of the platform, and the pre-pressed upper surface of the metal pipe protrudes outwardly from the groove. Next, the pre-pressed upper surface 213 of the metal pipe 210 is pressed in a single direction from the metal pipe 210 towards the platform so as to elongate the opposite longitudinal sides 215, 216 of the metal pipe 210 to the first upper protrusions 130, the second upper protrusions 140, the first lower protrusions 150 and the second lower protrusions 160, respectively.

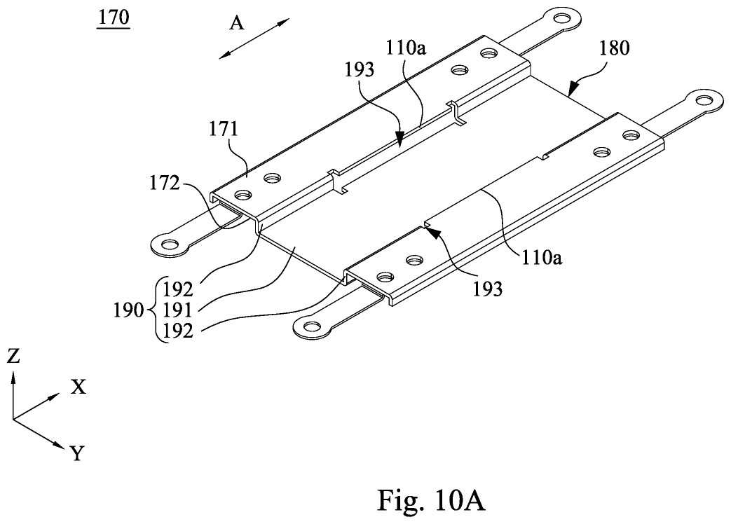

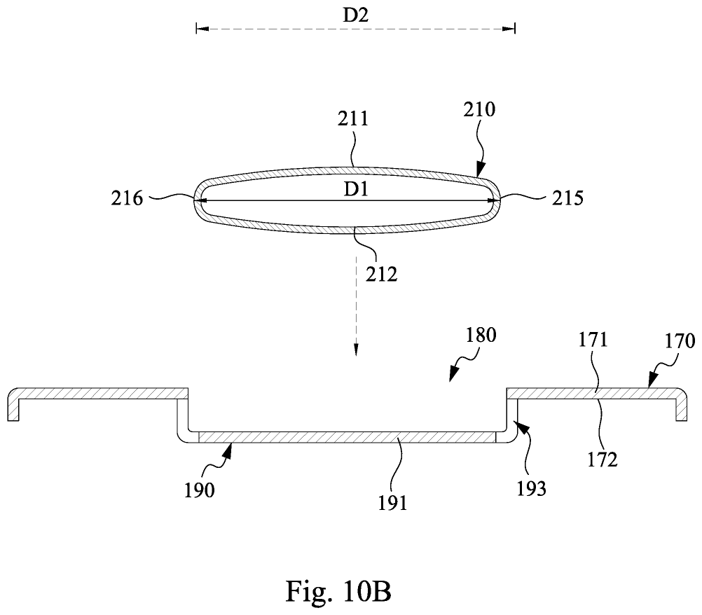

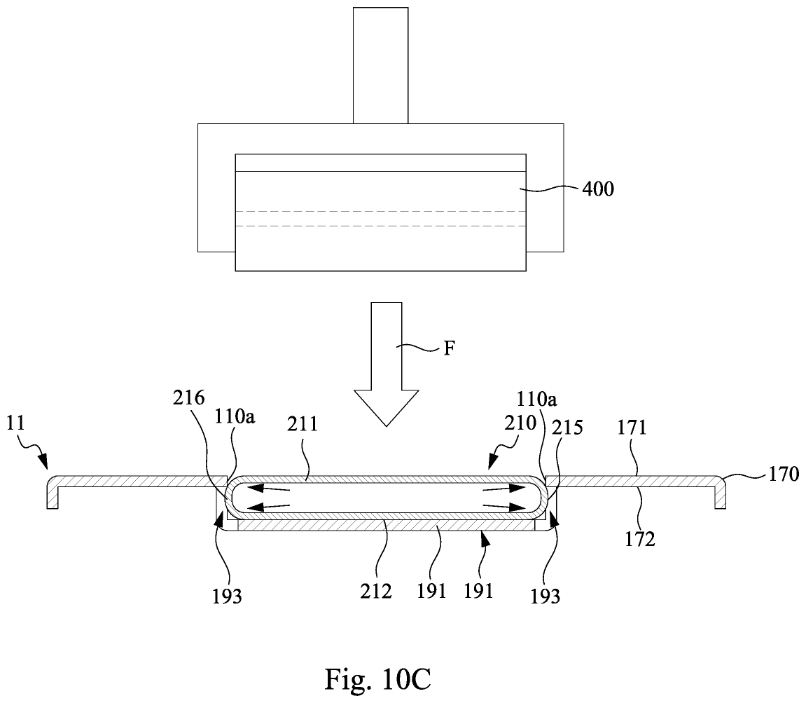

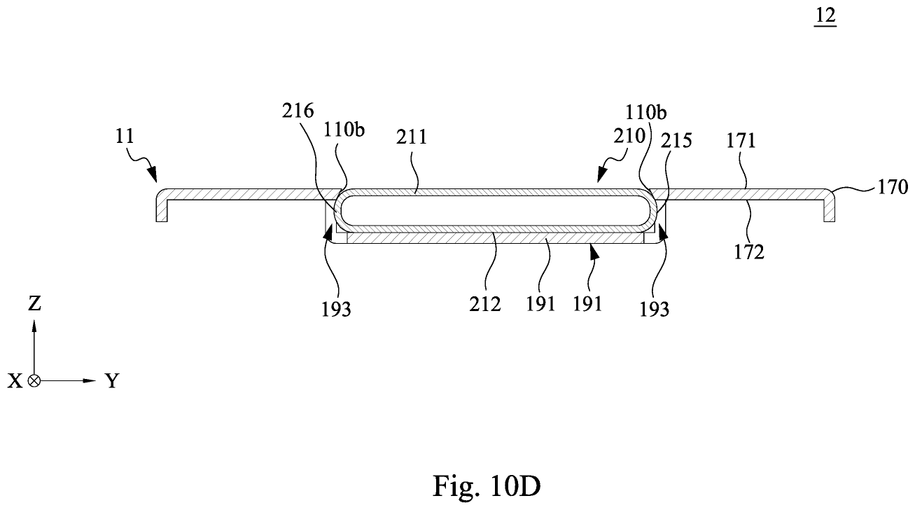

FIG. 10A to FIG. 100 are continuous operation views of a method of manufacturing a cooling module 11 according to one embodiment of the present disclosure. In another embodiment, the step 303 further includes detailed steps as follows. As shown in FIG. 10A, a sheet metal piece 170 is punched at the first surface 171 thereof, so that one part of the sheet metal piece 170 on the second surface 172 is convexly formed with an elongated convex portion 190. A blind groove 180 as a blind hole is formed in the elongated convex portion 190, and the blind groove 180 and the elongated convex portion 190 are parallel to each other.

The blind groove 180 includes a bottom plate 191, two inner walls 192 opposite to each other, and two hollow portions 193 formed on the inner walls 192, respectively. The bottom plate 191 is adjacent to the inner walls 192, respectively. The long axis direction A of each of the hollow portions 193 is parallel to the long axis direction A of the elongated convex portion 190.

As shown in FIG. 10B, the step 302 further includes that the metal pipe 210 is placed on the bottom plate 191 of the blind groove 180, so that the lower portion 212 of the metal pipe 210 contacts with the bottom plate 191, and the upper portion 211 of the metal pipe 210 protrudes out from the blind groove 180. The long axis direction A of the metal pipe 210 is parallel to the long axis direction A of the blind groove 180, and the cross-sectional width D1 of the metal pipe 210 is smaller than the maximum width D2 of the blind groove 180.

As shown in FIG. 100, a rolling process is performed on the upper portion 211 of the metal pipe 210, for example, a rolling tool (such as a roller 400) is used to contact the upper portion 211 of the metal pipe 210 with a specific force F, and roll on the upper portion 211 of the metal pipe 210 along the long axis direction A of the blind groove 180 so that the metal pipe 210 is deformed flat to elongate the opposite longitudinal sides 215, 216 of the metal pipe 210 to abut against the inner walls 192, wherein one part of each of the opposite longitudinal sides 215, 216 of the metal pipe 210 abuts against the inner walls 192 (FIG. 10A), the other part thereof extends into one of the hollow portions 193. Finally, the upper portion 211 of the metal pipe 210 for thermally conduction is flat and is flush with the first surface 171 of the sheet metal piece 170.

As shown in FIG. 10A and FIG. 100, two opposite inner sides of the blind groove 180 facing to each other further include a bearing surface 110a, respectively. The bearing surfaces 110a are planar, and face each other, and extend along the long axis direction A of the blind groove 180. Each of the bearing surface 110a is parallel to a X-Z plane imaginarily defined in FIG. 10A.

FIG. 10D is a cross-sectional view of the cooling module 12 of FIG. 100 according to another embodiment of the present disclosure. As shown in FIG. 10D, each of the bearing surfaces 110b of the opposite inner sides of the blind groove 180 is oblique rather than planar, so that each of the bearing surfaces 110b is actually inclined with respect to the X-Z plane that is imaginarily defined in FIG. 10D.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

What is claimed is:

1. A cooling module, comprising:
a thermally conductive plate comprising:
a plate body having a first surface, a second surface and a groove, the first surface and the second surface being opposite to each other, the groove penetrating through the plate body to adjoin the first surface and the second surface, respectively, wherein a first inner wall and a second inner wall being opposite to each other and collectively extending along an extending direction, are defined in the groove of the plate body;
at least one first upper protrusion protrusively disposed on the first surface and the first inner wall of the plate body;
at least one second upper protrusion protrusively disposed on the first surface and the second inner wall of the plate body, and extending towards the at least one first upper protrusion;
at least one first lower protrusion protrusively disposed on the first inner wall of the plate body, and extending towards the second inner wall; and
at least one second lower protrusion protrusively disposed on the second inner wall of the plate body, and extending towards the at least one first lower protrusion; and
a heat pipe located in the groove, and cooperatively secured by the at least one first upper protrusion, the at least one second upper protrusion, the at least one first lower protrusion and the at least one second lower protrusion.

2. The cooling module of claim 1, wherein the at least one first upper protrusion comprises:
a first convex portion protruding outwards from the first surface of the plate body; and
a first projection tooth connected to one side of the first convex portion and the first inner wall of the plate body, and the first projection tooth which extends towards the at least one second upper protrusion,
wherein the first projection tooth is formed with a first inclined surface directly pressing an upper surface of the heat pipe.

3. The cooling module of claim 2, wherein the at least one second upper protrusion comprises:
a second convex portion protruding outwards from the first surface of the plate body; and
a second projection tooth connected to one side of the second convex portion and the second inner wall of the plate body, and the second projection tooth which extends towards the at least one first upper protrusion,
wherein the second projection tooth is formed with a second inclined surface directly pressing the upper surface of the heat pipe, and a second inclined direction of the second inclined surface is intersected with a first inclined direction of the first inclined surface.

4. The cooling module of claim 3, wherein the plate body comprises:
at least one first concave recess concavely formed on the second surface of the plate body and connected to the first inclined surface of the first projection tooth: and
at least one second concave recess concavely formed on the second surface of the plate body and connected to the second inclined surface of the second projection tooth.

5. The cooling module of claim 2, wherein the at least one first lower protrusion is formed with a third inclined surface directly pressing a lower surface of the heat pipe; and
the at least one second lower protrusion is formed with a fourth inclined surface directly pressing the lower surface of the heat pipe,
wherein a first inclined direction of the first inclined surface is intersected with a third inclined direction of the third inclined surface, the third inclined direction of the third inclined surface is intersected with a fourth inclined direction of the fourth inclined surface.

6. The cooling module of claim 3, wherein the first convex portion comprises a first top surface and at least one first side surface, the first top surface adjoins the at least one first side surface and the first projection tooth, and the at least one first side surface adjoins the first surface of the plate body; and
the second convex portion comprises a second top surface and at least one second side surface, the second top surface adjoins the at least one second side surface and the second projection tooth, and the at least one second side surface adjoins the second surface of the plate body.

7. The cooling module of claim 6, wherein the first top surface of the first convex portion and a first top portion of the first projection tooth are coplanar with each other, the second top surface of the second convex portion and a second top portion of the second projection tooth are coplanar with each other, and a first bottom portion of the at least one first lower protrusion, a second bottom portion of the at least one second lower protrusion and the second surface of the plate body are collectively coplanar.

8. The cooling module of claim 2, wherein the at least one first upper protrusion, the at least one second upper protrusion, the at least one first lower protrusion and the at least one second lower protrusion are plural in number, respectively, the first upper protrusions and the first lower protrusions are alternately arranged on the first inner wall along the extending direction, the second upper protrusions and the second lower protrusions are alternately arranged on the second inner wall along the extending direction, wherein the heat pipe is directly clamped by the first upper protrusions, the second upper protrusions, the first lower protrusions and the second lower protrusions together.

9. The cooling module of claim 1, wherein a thermal conductivity of the heat pipe is greater than a thermal conductivity of the thermally conductive plate.

10. The cooling module of claim 1, wherein the heat pipe is with a hollow structure, and a cross section of the heat pipe is hollow and flat.

11. The cooling module of claim 1, wherein an upper surface of the at least one first upper protrusion, an upper surface of the at least one second upper protrusion and an upper surface of the heat pipe are collectively flush.

12. A method of manufacturing a cooling module, comprising:
(a) providing a thermally conductive plate having a groove thereon;
(b) placing a metal pipe into the groove of the thermally conductive plate; and
(c) squeezing the metal pipe located in the groove of the thermally conductive plate, such that the metal pipe is deformed flat to elongate two opposite longitudinal sides of the metal pipe towards two opposite inner walls of the groove respectively, and the metal pipe is secured in the groove by the thermally conductive plate.

13. The method of claim 12, wherein the step (a) further comprises:
performing a punching process on a sheet metal piece to form the thermally conductive plate having two upper protrusions and two lower protrusions, wherein the upper protrusions are formed on a top surface of the thermally conductive plate, located on the opposite inner walls of the groove, respectively, and extend toward each other, and the lower protrusions are formed on a bottom surface of the thermally conductive plate, located on the opposite inner walls of the groove, respectively, and extend toward each other, and the groove is connected to the top surface and the bottom surface of the thermally conductive plate, respectively.

14. The method of claim 13, further comprising:
before the step (b), performing a pre-pressing procedure to the metal pipe at the upper portion and the lower portion of the metal pipe, respectively, such that a pre-pressed upper surface and a pre-pressed lower surface are formed on the metal pipe, respectively.

15. The method of claim 14, further comprising:
before the step (b), disposing the thermally conductive plate without the metal pipe on a platform to face the groove towards a load surface of the platform;
the step (b) further comprises:
placing the metal pipe into the groove through a gap formed between the upper protrusions, wherein the pre-pressed lower surface of the metal pipe is directly contacted with the load surface of the platform, and the pre-pressed upper surface of the metal pipe protrudes outwardly from the groove; and
the step (c) further comprises:
pressing the pre-pressed upper surface of the metal pipe in a single direction from the metal pipe towards the load surface of the platform, such that the metal pipe that is deformed extends the opposite longitudinal sides thereof to abut against the upper protrusions and the lower protrusions, respectively, and fixedly sandwiched by the upper protrusions and the lower protrusions.

16. The method of claim 14, further comprising:
before the step (b), disposing the thermally conductive plate without the metal pipe on a clipping jig having an upper pressing mold and a lower pressing mold which are able to be shut together, wherein the thermally conductive plate is placed on a pressing area of the lower pressing mold facing towards the upper pressing mold;
the step (b) further comprises:
placing the metal pipe into the groove through a gap formed between the upper protrusions, wherein the pre-pressed upper surface and the pre-pressed lower surface of the metal pipe are protruded outwards from the groove towards the upper pressing mold and the lower pressing mold, respectively; and
the step (c) further comprises:
simultaneously pressing the pre-pressed upper surface and the pre-pressed lower surface of the metal pipe in confront directions through the clipping jig such that the opposite longitudinal sides of the metal pipe respectively elongate to abut against the upper protrusions and the lower protrusions.

17. The method of claim 16, wherein simultaneously pressing the pre-pressed upper surface and the pre-pressed lower surface of the metal pipe in confront directions through the clipping jig, further comprises:
thermally pressing the pre-pressed upper surface and the pre-pressed lower surface of the metal pipe through the clipping jig at a specific temperature.

18. The method of claim 12, wherein the step (a) further comprises:
punching a sheet metal piece from one surface to the other surface of the sheet metal piece to form an elongated convex portion on the other surface of the sheet metal piece,
wherein the groove is concavely formed on the elongated convex portion, and each of the opposite inner walls of the groove is formed with a hollow portion.

19. The method of claim 18, wherein the step (b) further comprises:
placing the metal pipe onto a bottom plate of the groove, wherein a width of a cross-section of the metal pipe is less than a minimum width of the groove, and one part of the metal pipe is protruded upwardly from the groove.

20. The method of claim 19, wherein the step (c) further comprises:
rolling and pressing the one part of the metal pipe by a rolling tool along a longitudinal direction of the groove such that the opposite longitudinal sides of the metal pipe respectively elongate to abut against the opposite inner walls of the groove, wherein a upper surface of the metal pipe that is flat is flush with the surface of the sheet metal piece.
